(19) United States
(12) Patent Application Publication
(10) Pub. No.: US 2009/0017604 A1
(43) Pub. Date: Jan. 15, 2009

(54) METHOD FOR FABRICATING A SEMICONDUCTOR DEVICE

(75) Inventors: Mao-Ying WANG, Taipei County (TW); Jer-Chyi WANG, Taoyuan County (TW); Wei-Hui HSU, Taoyuan County (TW); Liang-Pin CHOU, Taoyuan County (TW); Kuo-Hui SU, Taipei County (TW); Chang-Rong WU, Taipei County (TW); Chao-Sung LAI, Taoyuan County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/933,742

(22) Filed: Nov. 1, 2007

(30) Foreign Application Priority Data
Jul. 9, 2007 (TW) TW96124893

(51) Int. Cl. H01L 21/425

(52) U.S. Cl. 438/514; 257/E21.473

(57) ABSTRACT

A method for fabricating a semiconductor device is provided. The method for fabricating the semiconductor device comprises providing a substrate. Under an atmosphere containing a fluoride nitride compound, a plasma treatment process is performed to simultaneously fluorinate and nitrify a surface of the substrate. Thereafter, a dielectric layer is formed on the substrate.

### BACKGROUND OF THE INVENTION

1. Field of the Invention

The invention relates to a method for fabricating a semiconductor device, and more particularly relates to a method for fabricating a gate dielectric layer of a semiconductor device.

2. Description of the Related Art

In recent years, semiconductor device critical dimensions (CDs) have continually scaled downward. Accordingly, oxide layers used for gate dielectric have also shrunk to nanometer sizes. The continued shrinkage of device CDs, however, causes new problems for device performance. For example, problems such as device tunneling current, dielectric breakdown, uninformed dielectric thickness and poor device reliability occur when thickness of conventional gate dielectric layers such as an SiO₂ or an oxynitride layer becomes thinner than about 1 nm. High dielectric constant (high-k) dielectric materials are thus used to improve gate dielectric layer performance. Compared with the conventional low-k dielectric material, a high-k dielectric material has higher physical thickness under the same equivalent oxide thickness (EOT). But flatband voltage (V_{tb}) is changed due to charges in the high-k dielectric material, and device performance is also hindered. To solve the device tunneling current problem, a substrate pre-treatment process such as substrate nitridation can be used to form Si—N bonding in an interface between the substrate and the dielectric layer. Therefore, interface performances are improved. However, too much nitrogen atom in the interface induces positive charge trapping. Therefore, changing flatband voltage (V_{tb}) is changed.

Thus, a novel and reliable method for fabricating a gate dielectric layer of a semiconductor device for mitigating dielectric breakdown and device tunneling current is needed.

### SUMMARY OF THE INVENTION

To solve the above-described problems, a method for fabricating a semiconductor device is provided. An exemplary embodiment of a method for fabricating a semiconductor device comprises providing a substrate. A plasma treatment process is performed to simultaneously fluorinate and nitrify a surface of the substrate under an atmosphere containing a fluoride nitride compound. A dielectric layer is formed on the substrate.

Another method for fabricating a semiconductor device is provided. An exemplary embodiment of a method for fabricating a semiconductor device comprises providing a substrate. A plasma treatment process is performed to simultaneously fluorinate and nitrify a surface of the substrate under an atmosphere containing a fluoride nitride compound. A dielectric layer is formed on the substrate. A plasma treatment process is performed to simultaneously fluorinate and nitrify a surface of the dielectric layer under an atmosphere containing a fluoride nitride compound after forming the dielectric layer.

Another method for fabricating a semiconductor device is provided. An exemplary embodiment of a method for fabricating a semiconductor device comprises providing a substrate. A plasma treatment process is performed to simultaneously fluorinate and nitrify a surface of the substrate under an atmosphere containing a fluoride nitride compound. A dielectric layer is formed on the substrate. A plasma treatment process is performed to simultaneously fluorinate and nitrify a surface of the dielectric layer under an atmosphere containing a fluoride nitride compound during forming the dielectric layer.

Another method for fabricating a semiconductor device is provided. An exemplary embodiment of a method for fabricating a semiconductor device comprises providing a substrate. A dielectric layer is formed on the substrate. A plasma treatment process is performed to simultaneously fluorinate and nitrify a surface of the dielectric layer under an atmosphere containing a fluoride nitride compound.

Another method for fabricating a semiconductor device is provided. An exemplary embodiment of a method for fabricating a semiconductor device comprises providing a substrate. A dielectric layer is formed on the substrate. A plasma treatment process is performed to simultaneously fluorinate and nitrify a surface of the dielectric layer under an atmosphere containing a fluoride nitride compound. A plasma treatment process is performed to simultaneously fluorinate and nitrify a surface of the substrate under an atmosphere containing a fluoride nitride compound before forming of the dielectric layer.

Another method for fabricating a semiconductor device is provided. An exemplary embodiment of a method for fabricating a semiconductor device comprises providing a substrate. A dielectric layer is formed on the substrate. A plasma treatment process is performed to simultaneously fluorinate and nitrify a surface of the dielectric layer under an atmosphere containing a fluoride nitride compound during forming of the dielectric layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1a to 1d show cross sections of an exemplary embodiment of a process for fabricating a semiconductor device.

FIGS. 2a to 2b show cross sections of another exemplary embodiment of a process for fabricating a semiconductor device.

FIG. 3 shows a cross section of another exemplary embodiment of a process for fabricating a semiconductor device.

FIGS. 4a to 4d show cross sections of another exemplary embodiment of a process for fabricating a semiconductor device.

FIG. 5 shows a cross section of another exemplary embodiment of a process for fabricating a semiconductor device.

FIG. 6 shows a cross section of another exemplary embodiment of a process for fabricating a semiconductor device.

FIG. 7 is a capacitance versus gate applying voltage characteristic of an exemplary embodiment of the semiconductor device.

FIG. 8 shows the equivalent oxide thickness (EOT) and leakage current comparison for an exemplary embodiment of the semiconductor device and a conventional semiconductor device.

FIG. 9 shows the normalized gate current comparison for various exemplary embodiments of the semiconductor device.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

Wherever possible, the same reference numbers are used in the drawings and the descriptions to refer to the same or like parts.

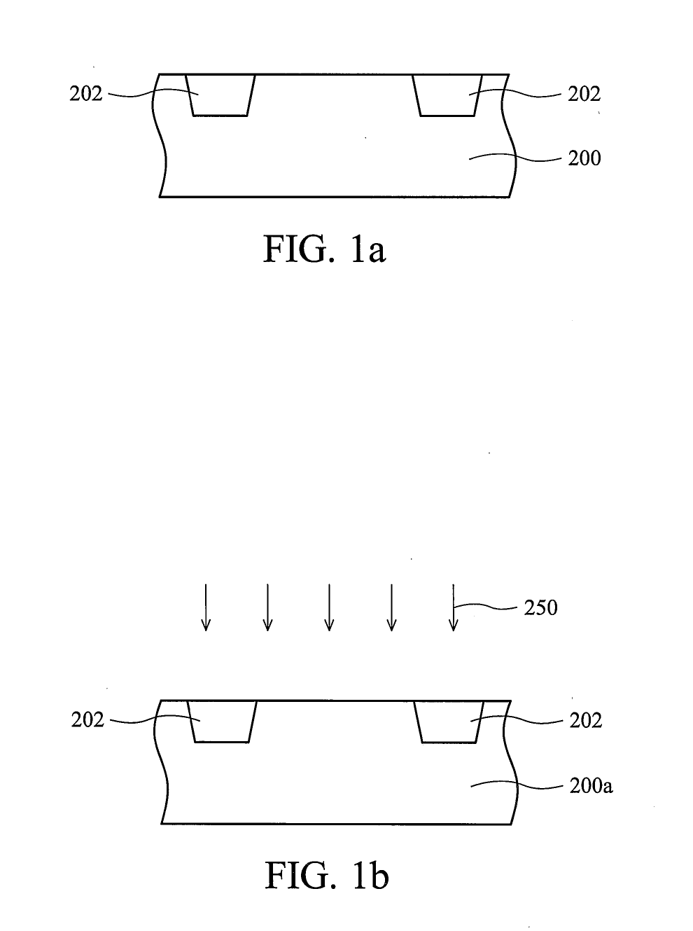

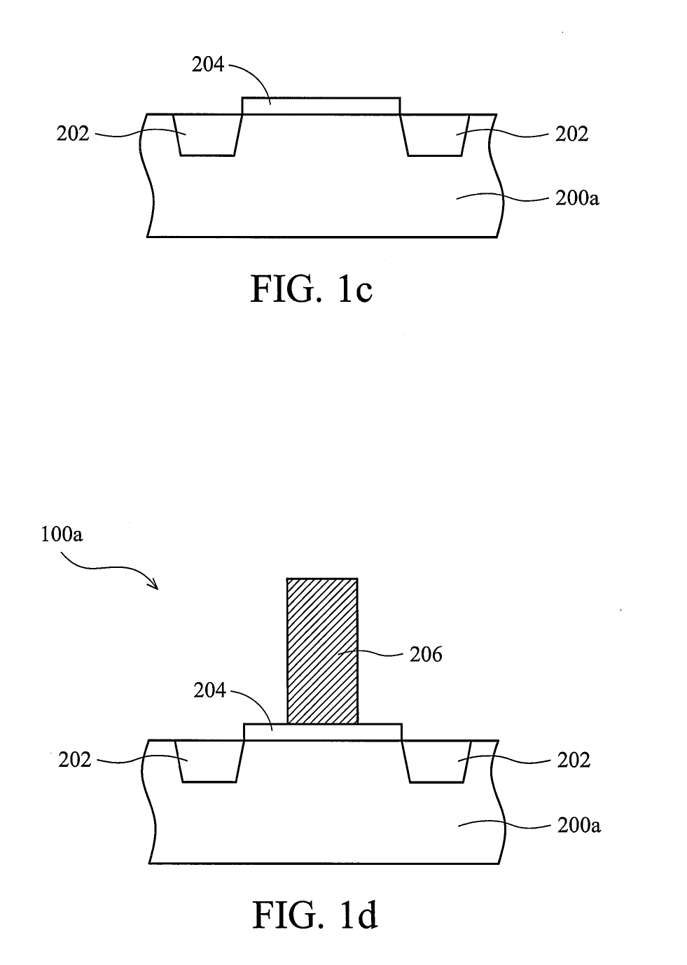

FIGS. 1a to 1d show cross sections of an exemplary embodiment of a process for fabricating a semiconductor device. With reference to FIG. 1a, the initial step of a first embodiment of forming a metal-insulator-semiconductor capacitor (MIS) is shown. A substrate 200 is provided. The substrate 200 may be a silicon substrate. Also, the substrate 200 may comprise SiGe, silicon on insulator (SOI), or other commonly used semiconductor materials. In one embodiment, a plurality of shallow trench isolations (STI) 202 is formed in the substrate 200 to isolate subsequent MISs. The shallow trench isolations (STI) may be formed by etching the substrate 200 to form recesses. Next, a dielectric material such as a high-density plasma oxide (HDP oxide) is filled in the recesses. A planarization process such as chemical mechanical polish (CMP) is performed for removing the excessive dielectric material to form STIs 202 in the substrate 200. In this embodiment, the substrate 200 serves as a bottom electrode of the MIS.

Referring to FIG. 1b, a surface of the substrate 200 is cleaned by a wet cleaning process such as an RCA cleaning process developed by RCA Corporation. In one embodiment of the invention, an RCA cleaning process is used to remove particles or organic pollutant on the surface of the substrate 200 by a standard cleaning 1 (SC-1) solution. SC-1 solution comprises a solvent of ammonium hydroxide (NH₄OH)/hydrogen peroxide (H₂O₂)/hydrogen oxide (H₂O) with a volume ratio of about 1:1:50. Next, a plasma treatment process 250 is performed to simultaneously fluorinate and nitrify a surface of the substrate 200 under an atmosphere containing a fluoride nitride compound. After performing the plasma treatment process 250, a substrate 200a is thus formed. The plasma treatment process 250 may be performed at a temperature around 200 or below 200. In this embodiment, the fluoride nitride compound may comprise NF₃.

FIG. 1c illustrates a formation of a dielectric layer 204. The dielectric layer 204 is then formed on the substrate 200a by methods such as thermal oxidation, chemical vapor deposition (CVD), or atomic layer CVD (ALCVD). The dielectric layer 204 may comprise oxide, nitride, oxynitride, oxycarbide or combinations thereof. The dielectric layer 204 may also comprise high-dielectric constant (k) (k>8) dielectric materials such as aluminum oxide (Al₂O₃), hafnium oxide (HfO₂), hafnium oxynitride (HfON), hafnium silicate (HfSiO4), zirconium oxide (ZrO₂), zirconium oxynitride (ZrON, zirconium silicate (ZrSiO₄), yttrium oxide (Y₂O₃), lanthalum oxide (La₂O₃), cerium oxide (CeO₂), titanium oxide (TiO₂), tantalum oxide (Ta₂O₅) or combinations thereof. In one embodiment, the dielectric layer 204 may be aluminum oxide (Al₂O₃). The dielectric layer 204 serves as an insulating layer for the MIS. Next, an anneal process, for example, thermal annealing, flash annealing, laser annealing or the like, is performed after formation of the dielectric layer.

FIG. 1d illustrates a formation of a conductive layer 206. A conductive layer may be formed on the dielectric layer 204 by physical vapor deposition (PVD). A portion of the conductive layer is then removed to form a conductive layer 206 by subsequent photolithography and anisotropic etching processes. In some embodiments, other deposition processes such as sputtering, low pressure CVD (LPCVD), atomic-layer CVD (ALCVD) or electroless plating may also be used to form the conductive layer 206. The conductive layer 206 may comprise a single layer of Au, Pt, Al, Cu or alloys thereof. The conductive layer 206 may also comprise a composite layer of TiN/AlCu. In one embodiment, the conductive layer 206 is used as a top electrode for the MIS. Thus, the formation of a MIS 100a is completely formed.

As illustrated, one embodiment of the invention provides an MIS 100a comprising a substrate 200a. A dielectric layer 204 is formed on the substrate 200a. A conductive layer 206 is formed on the dielectric layer 204, wherein a surface of the substrate 200a is fluorinated and nitrified by a plasma treatment process.

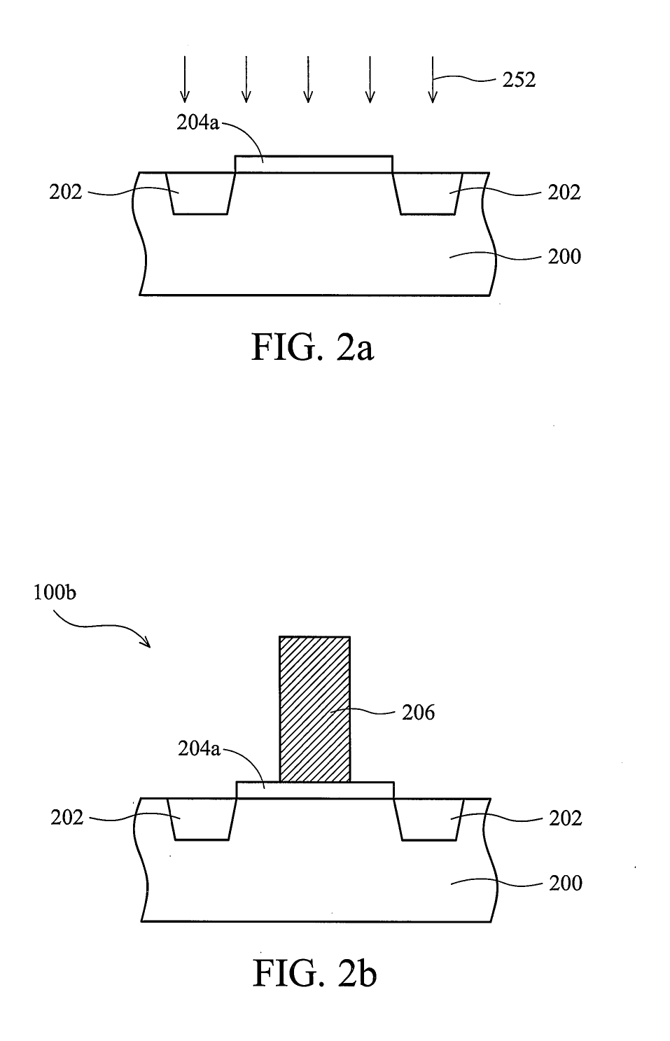

FIGS. 2a to 2b show cross sections of another exemplary embodiment of a process for fabricating a semiconductor device. FIG. 2a shows the initial step of another embodiment for forming a metal-insulator-semiconductor capacitor (MIS). A plasma treatment process 252 is performed to simultaneously fluorinate and nitrify a surface of the dielectric layer 204 under an atmosphere containing a fluoride nitride compound. Alternatively, the plasma treatment process 252 may be performed during formation of the dielectric layer 204. After performing the plasma treatment process 252, a dielectric layer 204a is thus formed. The plasma treatment process 252 may be performed at a temperature of around 200 or below 200. In this embodiment, the fluoride nitride compound may comprise NF₃. The same formation processes of the top conductive layer 206 which is later used as a top electrode as shown in FIGS. 1a to 1d can be referred to in the previous description.

FIG. 2b illustrates a formation of a conductive layer 206. A conductive layer may be formed on the dielectric layer 204a by physical vapor deposition (PVD). A portion of the conductive layer is then removed to form a conductive layer 206 on the dielectric layer 204a by subsequent photolithography and anisotropic etching processes. In some embodiments, other deposition processes such as sputtering, low pressure CVD (LPCVD), atomic-layer CVD (ALCVD) or electroless plating may also be used to form the conductive layer 206. The conductive layer 206 may comprise a single layer of Au, Pt, Al, Cu or alloys thereof. The conductive layer 206 may also comprise a composite layer of TiN/AlCu. In one embodiment, the conductive layer 206 is used as a top electrode of the MIS. Thus, the formation of a MIS 100b is completely formed.

As illustrated, one embodiment of the invention provides an MIS 100b comprising a substrate 200a. A dielectric layer 204a is formed on the substrate 200a. A conductive layer 206 is formed on the dielectric layer 204a, wherein a surface of the dielectric layer 204a is simultaneously fluorinated and nitrified by a plasma treatment process.

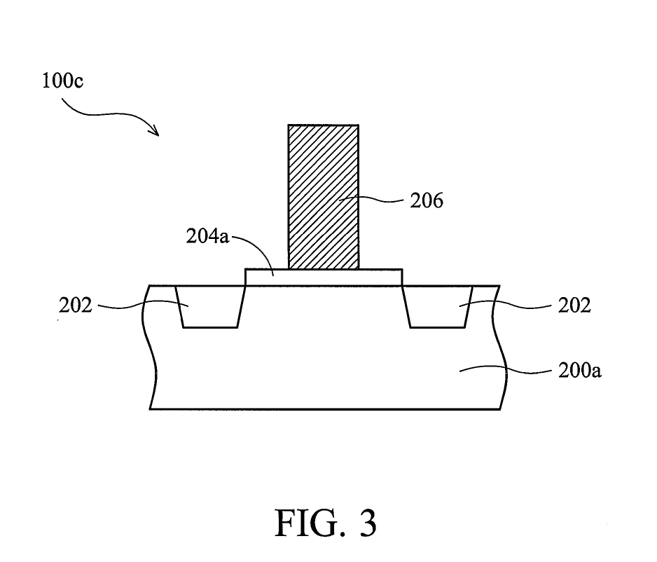

FIG. 3 shows a cross section of another exemplary embodiment of a process for fabricating a MIS 100c. The MIS 100c comprises a substrate 200a. A dielectric layer 204a is formed on the substrate 200a, wherein the surfaces of the substrate 200a and of the dielectric layer 204a are simultaneously fluorinated and nitrified by a plasma treatment process, respectively. The same formation processes as shown in FIGS. 1a to 1d and 2a to 2b can be referred to in the previous description and are not repeated for brevity.

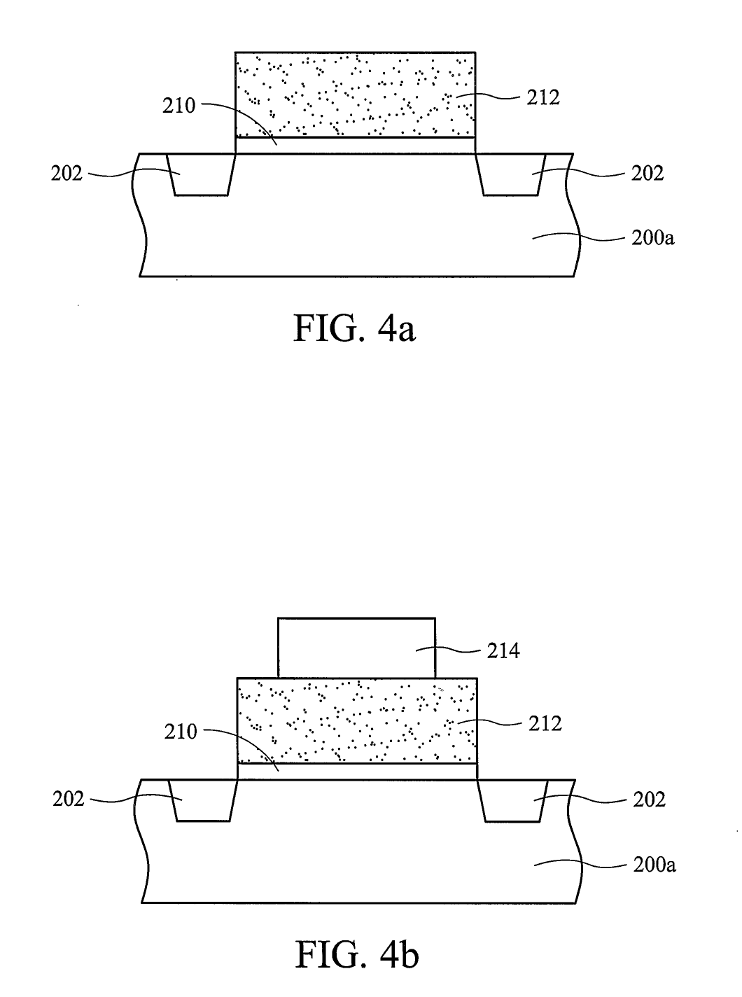

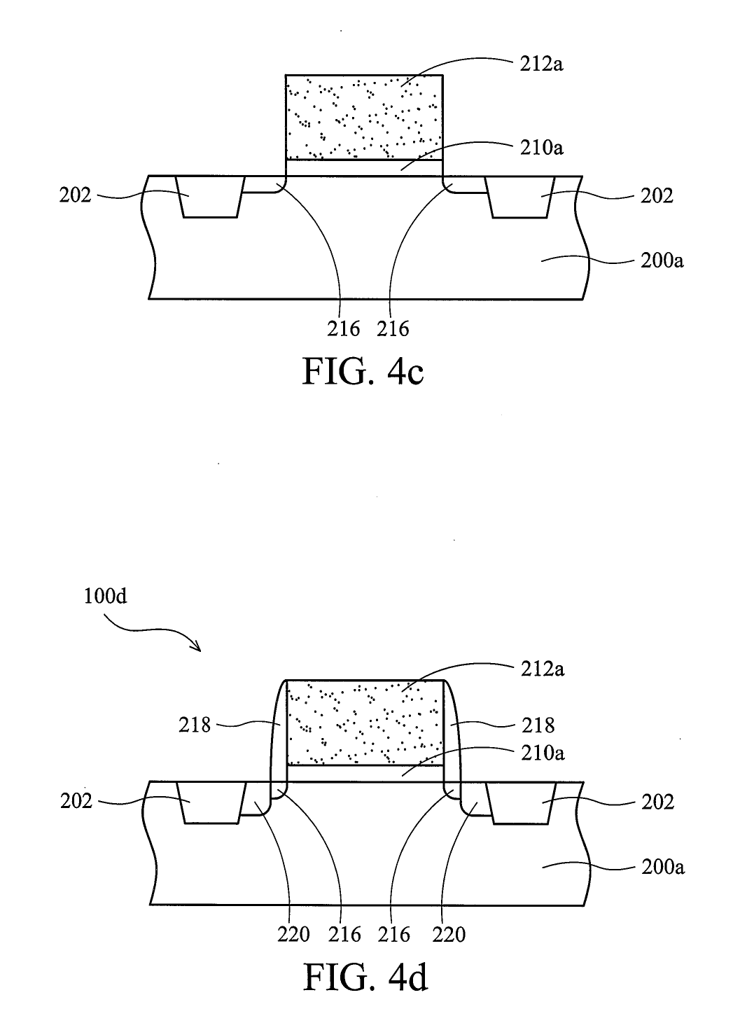

FIGS. 4a to 4d show cross sections of another exemplary embodiment of a process for fabricating a semiconductor device. FIG. 4a shows the initial step of a first embodiment for forming a metal-oxide-semiconductor transistor (MOS transistor). A substrate 200 as shown in FIG. 1a is provided. The substrate 200 as shown in FIG. 1a is preferably a silicon substrate. Also, the substrate 200 may comprise SiGe, silicon on insulator (SOI), and other commonly used semiconductor substrates. In one embodiment, a plurality of shallow trench isolations (STI) 202 is formed in the substrate 200 as shown in FIG. 1a to isolate subsequence MOS devices. The shallow trench isolations (STI) may be formed by etching the substrate 200 to form recesses. Next, a dielectric material such as a high-density plasma oxide (HDP oxide) is filled in the recesses. A planarization process such as chemical mechanical polish (CMP) is performed for removing the excessive dielectric material to form STIs 202 in the substrate 200 as shown in FIG. 1a.

Next, a surface of the substrate 200 as shown in FIG. 1a is cleaned by a wet cleaning process such as an RCA cleaning process developed by RCA Corporation. In one embodiment of the invention, the RCA cleaning process is used to remove particles or organic pollutant on the surface of the substrate 200 as shown in FIG. 1a by a standard cleaning 1 (SC-1) solution. SC-1 solution comprises a solvent of ammonium hydroxide (NH₄OH)/hydrogen peroxide (H₂O₂)/hydrogen oxide (H₂O) with a volume ratio of about 1:1:50. Next, a plasma treatment process is performed to simultaneously fluorinate and nitrify a surface of the substrate 200 under an atmosphere containing a fluoride nitride compound. After performing the plasma treatment process, a substrate 200a as shown in FIG. 4a is thus formed. The plasma treatment process may be performed at a temperature of around 200 or below 200. In this embodiment, the fluoride nitride compound may comprise NF₃.

A dielectric layer 210 is then formed on the substrate 200a by methods such as thermal oxidation, chemical vapor deposition (CVD), or atomic layer CVD (ALCVD). The dielectric layer 210 may comprise oxide, nitride, oxynitride, oxycarbide or combinations thereof. The dielectric layer 210 may also comprise high-dielectric constant (k) (k>8) dielectric materials such as aluminum oxide (Al₂O₃), hafnium oxide (HfO₂), hafnium oxynitride (HfON), hafnium silicate (HfSiO4), zirconium oxide (ZrO₂), zirconium oxynitride (ZrON, zirconium silicate (ZrSiO₄), yttrium oxide (Y₂O₃), lanthalum oxide (La₂O₃), cerium oxide (CeO₂), titanium oxide (TiO₂), tantalum oxide (Ta₂O₅) or combinations thereof. In this embodiment, the dielectric layer 210 may be aluminum oxide (Al₂O₃).

A conductive layer 212 is next formed on the dielectric layer 210 by thin film deposition process such as CVD. The conductive layer 212 may comprise silicon or polysilicon. The conductive layer 212 is preferably doped to reduce sheet resistance. Alternatively, the conductive layer 212 may comprise amorphous silicon.

As shown in FIG. 4b, a patterned masking layer 214, for example, a photoresist layer, is formed on the conductive layer 212. Next, the conductive layer 212 and the dielectric layer 210 which are not covered by the patterned masking layer 214 are removed to form a patterned conductive layer 212a and a patterned dielectric layer 210a as shown in FIG. 4c. The patterned masking layer 214 is then removed. In this embodiment, the patterned conductive layer 212a and the patterned dielectric layer 210a are used as a gate and a gate dielectric layer of the MOS transistor, respectively.

Next, as shown in FIG. 4c, an ion implantation process is performed to form a plurality of lightly doped source/drain (LDD) regions 216 around the patterned conductive layer 212a in the substrate 200a by using the patterned conductive layer 212a and the patterned dielectric layer 210a as masks.

As shown in FIG. 4d, a pair of spacers 218 may be formed along sidewalls of the patterned conductive layer 212a and the patterned dielectric layer 210a. As known in the art, spacers 218 may be formed by blanketly depositing a dielectric layer over the substrate 200a, the patterned conductive layer 212a and the patterned dielectric layer 210a followed by etching back the dielectric layer using anisotropic etching. The spacers 218 may be formed of a single dielectric layer as shown in FIG. 4d or a composite layer including more than one dielectric layer, for example, a silicon nitride layer on a silicon oxide liner (not shown). Also as shown in FIG. 4d, an ion implantation process is then performed to form a plurality of source/drain regions 220 around the patterned conductive layer 212a in the substrate 200a using the patterned conductive layer 212a, the patterned dielectric layer 210a and spacers 218 as masks. Thus, the formation of a MOS transistor 100d is completely formed.

As illustrated, one embodiment of the invention provides an MOS transistor 100d comprising a substrate 200a. A patterned dielectric layer 210a and a patterned conductive layer 212a are formed on the substrate 200a in sequence. A pair of spacers 218 is formed along sidewalls of the patterned conductive layer 212a and the patterned dielectric layer 210a. A plurality of lightly doped source/drain (LDD) regions 216 and a plurality of source/drain regions 220 are formed in the substrate 200a, wherein a surface of the substrate 200a is simultaneously fluorinated and nitrified by a plasma treatment process.

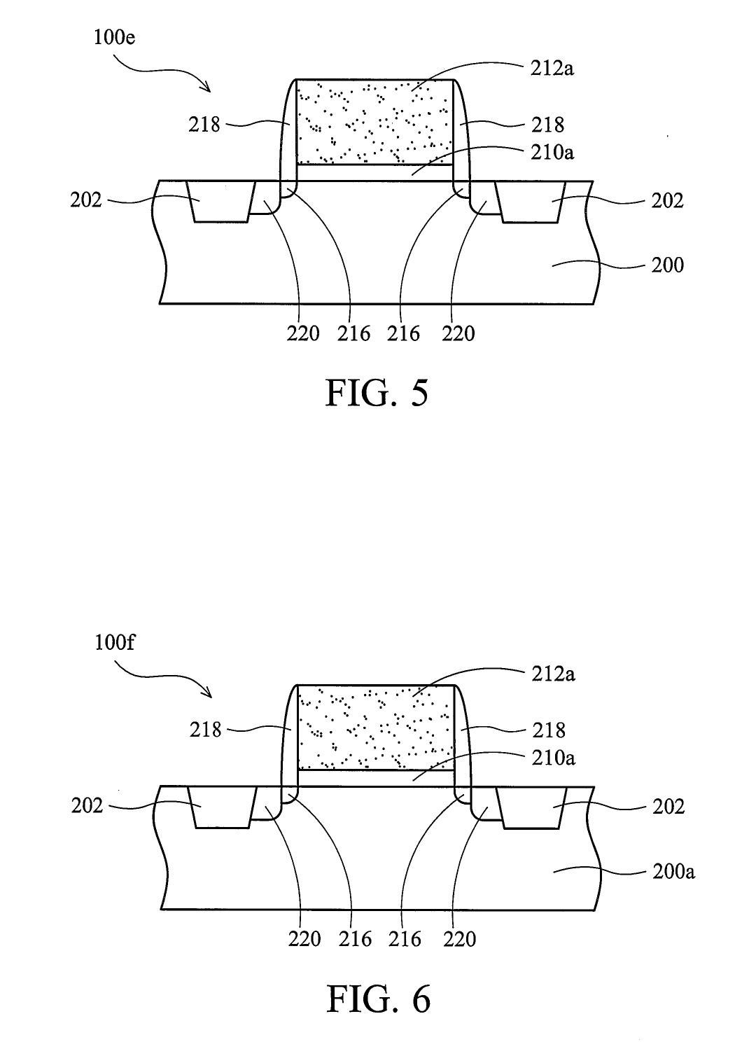

FIG. 5 shows a cross section of another exemplary embodiment of a process for fabricating a MOS transistor 100e. The MOS transistor 100e comprises a substrate 200. A patterned dielectric layer 210a and a patterned conductive layer 212a are formed on the substrate 200 in sequence. A pair of spacers 218 is formed along sidewalls of the patterned conductive layer 212a and the patterned dielectric layer 210a. A plurality of lightly doped source/drain (LDD) regions 216 and a plurality of source/drain regions 220 are formed in the substrate 200, wherein a surface of the patterned dielectric layer 210a is simultaneously fluorinated and nitrified by a plasma treatment process. Alternatively, the plasma treatment process may be performed during formation of the dielectric layer 210 as shown in FIG. 4a. The same formation processes as shown in FIGS. 4a to 4d can be referred to in the previous description and are not repeated for brevity.

FIG. 6 shows a cross section of another exemplary embodiment of a process for fabricating a MOS transistor 100f. The MOS transistor 100f comprises a substrate 200a. A patterned dielectric layer 210a and a patterned conductive layer 212a are formed on the substrate 200a in sequence. A pair of spacers 218 is formed along sidewalls of the patterned conductive layer 212a and the patterned dielectric layer 210a. A plurality of lightly doped source/drain (LDD) regions 216 and a plurality of source/drain regions 220 are formed in the substrate 200a, wherein surfaces of the substrate 200a and the patterned dielectric layer 210a are simultaneously fluorinated and nitrified by a plasma treatment process, respectively. Alternatively, the plasma treatment process may be performed during formation of the dielectric layer 210 as shown in FIG. 4a. The same formation processes as shown in FIGS. 4a to 4d and 5 can be referred to in the previous description and are not repeated for brevity.

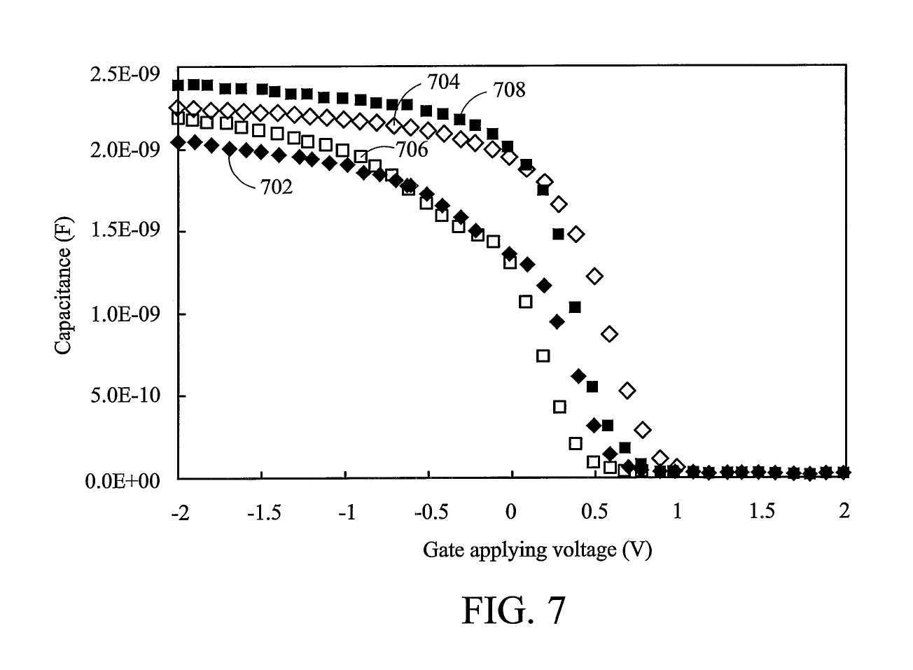

FIGS. 7 to 9 show electrical performances of some exemplary embodiments of a semiconductor device. FIG. 7 is a capacitance versus gate applying voltage characteristic (C-V curve) of an exemplary embodiment of the semiconductor device. There are four MIS samples for capacitance versus gate applying voltage characteristic comparison. And all dielectric layers of these four MIS samples have a physical thickness of about 50 Å. The curve line 708 shows a capacitance of the MIS 100a with a simultaneously fluorinated and nitrified substrate using a plasma treatment process, and a dielectric layer subjected to an annealing process. The curve line 702 shows a capacitance of a MIS with a substrate not subjected to a plasma treatment process and a dielectric layer not subjected to an annealing process. The curve line 704 shows a capacitance of a MIS with a substrate not subjected to a plasma treatment process but only a dielectric layer subjected to an annealing process. The curve line 706 shows a capacitance of a MIS with a substrate subjected to a plasma treatment process but a dielectric layer not subjected to an annealing process. In addition, an interface trap density between the substrate and the dielectric layer is extracted form the C-V curve. As shown in the line 708, no capacitance stretch-out phenomenon occurs on the MIS 100a as the interface traps are filled by the fluorine and nitrogen atoms of NF₃ following the plasma treatment process. Thus, reducing the interface trap density is reduced.

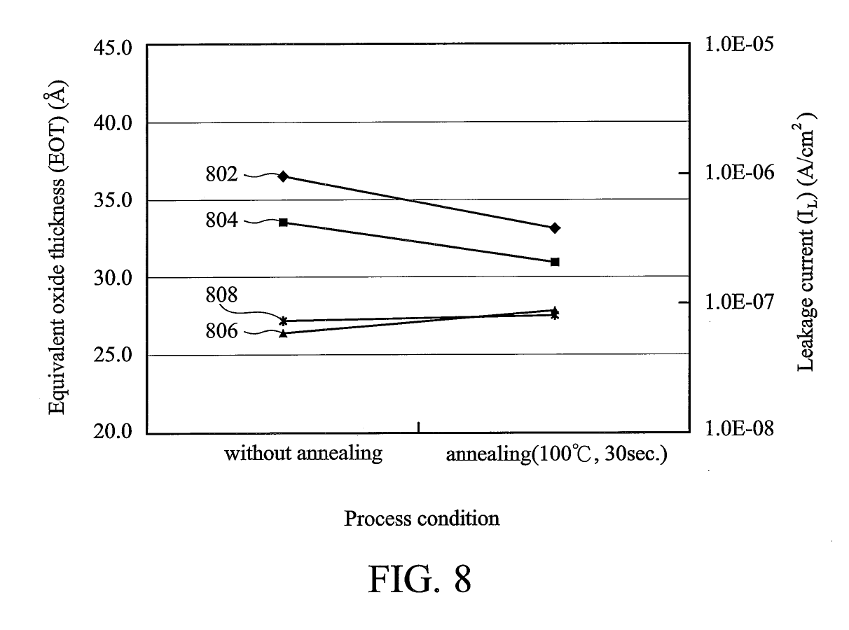

FIG. 8 shows the equivalent oxide thickness (EOT) and leakage current (I_{L}) comparison for an exemplary embodiment of the semiconductor device and a conventional semiconductor device. There are four MOS transistor samples for comparison, and physical thicknesses of dielectric layers of these samples are all about 50 Å. Leakage current is measured with −1V gate applying voltage. The curve line 804 shows an EOT versus process condition characteristic of a MOS transistor with a substrate not subjected to a plasma treatment. The curve line 806 shows a leakage current versus process condition characteristic of the MOS transistor 100d. The curve line 808 shows a leakage current versus process condition characteristic of a MOS transistor with a substrate not subjected to a plasma treatment process. As shown in the line 802 and the line 804, a MOS transistor subjected to an annealing process has a 10% reduced EOT. Compared with a MOS transistor with a substrate not subjected to a plasma treatment process, a MOS transistor with a substrate subjected to a plasma treatment process also has a 10% reduced EOT. The curve Line 806 and line 808 do not present the strong relationship between leakage current and plasma treatment process or annealing process. The leakage current of the line 806 and 808 are all about 1E⁻⁷ A/cm². It is known that the MOS transistor 100d has lower EOT than the conventional MOS transistor because the MOS transistor 100d has more Si—F bonding in the substrate using a plasma treatment process. Therefore, less native oxide will be grown on the substrate during thermal process or surface transferring. Thus, device leakage current and reliability of the subsequence dielectric layer can be improved.

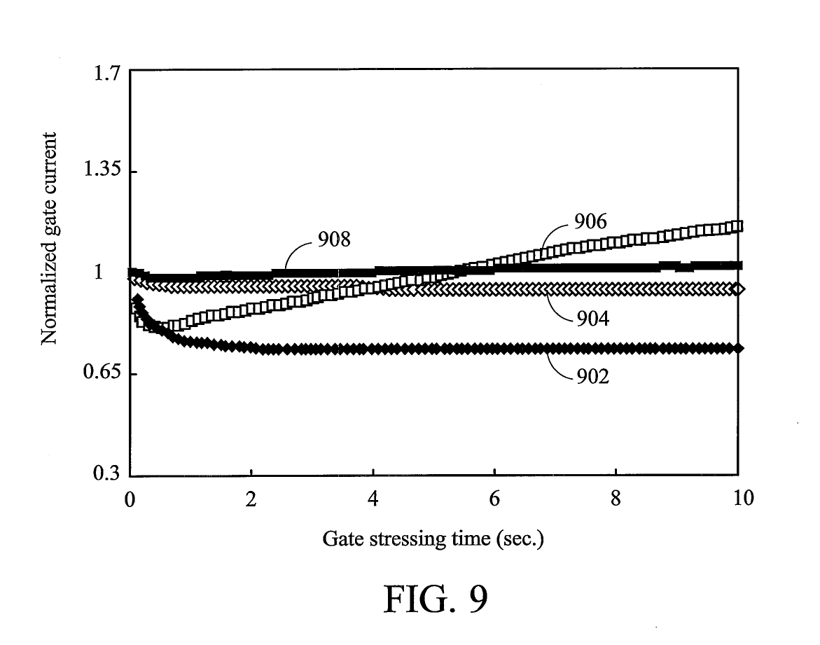

FIG. 9 shows the normalized gate current comparison for various exemplary embodiments of the semiconductor device. There are four MOS transistor samples for comparison, and physical thicknesses of dielectric layers of these samples are all about 50 Å. Gate current measured by −5.75V gate applying voltage, and then normalized by a measured gate current at a gate stressing time of about 0.1 second to have a normalized gate current. The curve line 908 shows a normalized gate current of the MOS transistor 100d with a fluorinated and nitrified substrate using a plasma treatment process, and a dielectric layer subjected to an annealing process. The curve line 902 shows a normalized gate current of the MOS transistor with a substrate not subjected to a plasma treatment process, and a dielectric layer subjected not to an annealing process. The curve line 904 shows a normalized gate current of the MOS transistor with a substrate not subjected to a plasma treatment process but only a dielectric layer subjected to an annealing process. The curve line 906 shows a normalized gate current of the MOS transistor with a substrate subjected to a plasma treatment process but a dielectric layer not subjected to an annealing process. As shown in the curve line 906, a normalized gate current of the MOS transistor with substrate plasma treatment process shows a curve that goes downward first and then upward. That is, the curve line 906 shows that the gate dielectric layer traps electron first and then captures hole. Compared with the MOS transistor with only an annealing process (Line 904), the MOS transistor 100d has a fixed normalized gate current showing less electron and hole trapping of the gate dielectric layer.

In the exemplary embodiment of the semiconductor device, the interface between the substrate and the dielectric layer is simultaneously fluorinated and nitrified using a plasma treatment process. The fluorinated and nitrified interface has some advantages such as decreased process steps, reducing the interface trap density of the dielectric layer, and improving EOT, device leakage current and dielectric layer reliability. The plasma treatment process may be performed at a temperature below 200° C., thus device performance is not affected.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a semiconductor device, comprising:
providing a substrate;
performing a plasma treatment process to simultaneously fluorinate and nitrify a surface of the substrate under an atmosphere containing a fluoride nitride compound; and
forming a dielectric layer on the substrate.

2. The method for fabricating the semiconductor device as claimed in claim 1, wherein the fluoride nitride compound comprises NF₃.

3. The method for fabricating the semiconductor device as claimed in claim 1 further comprising a step of performing an anneal process after forming of the dielectric layer.

4. The method for fabricating the semiconductor device as claimed in claim 1 further comprising performing a plasma treatment process to simultaneously fluorinate and nitrify a surface of the dielectric layer under an atmosphere containing a fluoride nitride compound after forming of the dielectric layer.

5. The method for fabricating the semiconductor device as claimed in claim 1 further comprising performing a plasma treatment process to simultaneously fluorinate and nitrify the dielectric layer under an atmosphere containing a fluoride nitride compound during forming of the dielectric layer.

6. The method for fabricating the semiconductor device as claimed in claim 1 further comprising forming a conductive layer on the dielectric layer.

7. The method for fabricating the semiconductor device as claimed in claim 6, wherein the substrate and the conductive layer are used as a bottom electrode and a top electrode, respectively.

8. The method for fabricating the semiconductor device as claimed in claim 6 further comprising:
forming a patterned masking layer on the conductive layer;
partially removing the conductive layer and the dielectric layer to form a patterned conductive layer and a patterned dielectric layer;
removing the patterned masking layer; and
performing an ion implantation process to form a plurality of doped regions on the substrate.

9. The method for fabricating the semiconductor device as claimed in claim 8, wherein the patterned conductive layer is a gate layer, the patterned dielectric layer is a gate dielectric layer, and the doped regions are source/drain regions.

10. A method for fabricating a semiconductor device, comprising:
providing a substrate;
forming a dielectric layer on the substrate; and
performing a plasma treatment process to simultaneously fluorinate and nitrify a surface of the dielectric layer under an atmosphere containing a with fluoride nitride compound.

11. The method for fabricating the semiconductor device as claimed in claim 10, wherein the fluoride nitride compound comprises NF₃.

12. The method for fabricating the semiconductor device as claimed in claim 10 further comprising performing an anneal process after forming of the dielectric layer.

13. The method for fabricating the semiconductor device as claimed in claim 10 further comprising performing a plasma treatment process to simultaneously fluorinate and nitrify a surface of the substrate under an atmosphere containing a fluoride nitride compound before forming of the dielectric layer.

14. The method for fabricating the semiconductor device as claimed in claim 10 further comprising performing a plasma treatment process to simultaneously fluorinate and nitrify the dielectric layer under an atmosphere containing a fluoride nitride compound during forming of the dielectric layer.

15. The method for fabricating the semiconductor device as claimed in claim 10 further comprising forming a conductive layer on the dielectric layer.

16. The method for fabricating the semiconductor device as claimed in claim 15 further comprising:
forming a patterned masking layer on the conductive layer;
partially removing the conductive layer and the dielectric layer to form a patterned conductive layer and a patterned dielectric layer;
removing the patterned masking layer; and
performing an ion implantation process to form a plurality of doped regions on the substrate.

17. The method for fabricating the semiconductor device as claimed in claim 16, wherein the patterned conductive layer is a gate layer, the patterned dielectric layer is a gate dielectric layer, and the doped regions are source/drain regions.
